(19) United States
(12) Patent Application Publication
(10) Pub. No.: US 2019/0044029 A1
(43) Pub. Date: Feb. 7, 2019

(54) MUTILAYER STRUCTURE CONTAINING A CRYSTAL MATCHING LAYER FOR INCREASED SEMICONDUCTOR DEVICE PERFORMANCE

(71) Applicant: Tivra Corporation, Pleasant Hill, CA (US)

(72) Inventors: Francisco Machuca, Oakland, CA (US); Robert Weiss, San Francisco, CA (US)

(21) Appl. No.: 16/155,825

(22) Filed: Oct. 9, 2018

Related U.S. Application Data
(63) Continuation of application No. 15/194,517, filed on Jun. 27, 2016.
(60) Provisional application No. 62/184,692, filed on Jun. 25, 2015.
(60) Provisional application No. 62/233,157, filed on Sep. 25, 2015.

(51) Int. Cl. H01L 33/32; H01L 29/423; H01L 29/04; H01L 29/10; H01L 21/02; H01L 33/12; H01L 33/00; H01L 29/778; H01L 23/36; H01L 29/20; H01L 29/417; H01L 33/40

(52) U.S. Cl. CPC H01L 33/32; H01L 29/42316; H01L 29/04; H01L 29/1075; H01L 21/02609; H01L 33/12; H01L 33/405; H01L 29/7789; H01L 29/7788; H01L 29/7786; H01L 23/36; H01L 29/2003; H01L 29/41758; H01L 33/0075

(57) ABSTRACT

A multilayer structure comprising a crystal matching layer deposited on a substrate. The crystal matching layer is capable of being used as an ohmic contact, thermal heat sink, and reflective layer. The unique properties of the crystal matching layer allows for the reduction of size of semiconductor devices, a reduction in the fabrication time of semiconductor devices, high current capabilities, high voltage standoff capabilities, and other advantages.

### CROSS REFERENCE TO RELATED APPLICATIONS

The present application is a continuation of U.S. application Ser. No. 15/194,517, titled “MULTILAYER STRUCTURE CONTAINING A CRYSTAL MATCHING LAYER FOR INCREASED SEMICONDUCTOR DEVICE PERFORMANCE,” filed Jun. 27, 2016, which claims benefit under 35 USC 119 (e) of U.S. Provisional Application No. 62/184,692 entitled “Power Devices and LED Architectures Enabled by Bulk Quality Seeded Growth of a Member in the Solid Solution of AlGaN—InGaN using Group III-Nitride Crystal Matching Layer (“CML”) film” filed Jun. 25, 2015, and of U.S. Provisional Application No. 62/233,157 entitled “Crystalline Semiconductor Growth on Amorphous and Poly-Crystalline Substrates” filed Sep. 25, 2015, the contents of which are incorporated herein by reference in their entirety.

The present application is related to U.S. patent application Ser. No. 14/106,657 entitled “Substrate Structures and Methods” filed Dec. 13, 2013; and to U.S. Pat. No. 8,956,952 entitled “Multilayer Substrate Structure and Method of Manufacturing the Same” filed Jun. 14, 2012, the contents of which are incorporated herein by reference in their entirety.

### TECHNICAL FIELD

The present invention is related to a multilayer semiconductor structure.

### BACKGROUND

Today semiconductor devices for high brightness LEDs and power semiconductor devices, including high power low frequency switching, blocking diodes, and high frequency switching devices, have found an undeniable home with wide bandgap semiconductors in the solid solution of AlGaN—InGaN. AlGaN—InGaN and other group III-Nitride (III-N) semiconductors have properties of high dielectric break down fields (withstand 1-10 MV/cm Fields), high standoff voltages (>1000 Volts), extremely low on-resistance (low parasitic contact and mobility channel resistance), extremely high saturation drift velocity of carriers, extremely high temperature of operation due to the large bond energies of Ga—N and Al—N, and extremely high radiation hardness for harsh environments.

III-N semiconductors may be used in high electron mobility transistors (HEMTs) devices and Light Emitting Diode devices. Yet in light of a host of material improvements potentially leading to improved electronic and opto-electronic properties, performance obstacles remain for LEDs to transition to the mainstream to address general lighting requirements world-wide. Today High Brightness LEDs are 50-60% of their theoretical efficacy, suffer from high current densities in lateral devices, and show significant efficiency droop at high drive currents. For the past decade, power transistors have demonstrated improved performance over silicon based switching and power devices. However, crystalline quality of wafers, limited wafer diameters for wide bandgap substrates, lower than expected packing density limited by source drain contact spacing, and reliability of GaN based transistors remain problems in commercialization of GaN based power devices hindering development of a mature device industry.

### BRIEF SUMMARY

Various embodiments of the invention seek to create an improved multilayer structure that is capable of being used in many semiconductor based applications (e.g. LEDs, HEMTs, RF filters) by utilizing of a crystal matching layer.

In one embodiment, the objects of the various embodiments of the invention are achieved by creating a multilayer structure comprising a substrate, a crystal matching layer formed on the substrate, a semiconductor layer formed on the crystal matching layer, and a device layer formed on the semiconductor layer. The crystal matching layer acts an ohmic contact for the device layer and is substantially lattice matched to the semiconductor layer.

In one embodiment, the device layer is comprised of a HEMT that is capable of operating at high power and/or high speed.

In one embodiment, the device layer is comprised of a LED that is capable of producing visible or ultraviolet light.

In one embodiment, the device layer is comprised of a radio frequency filter.

In one embodiment, a coefficient of thermal expansion of the crystal matching layer is substantially matched to the coefficient of thermal expansion of the semiconductor layer. In an alternate embodiment, the coefficient of thermal expansion of the semiconductor layer is substantially matched to a coefficient of thermal expansion of the substrate.

In one embodiment, the crystal matching layer operates as a heat sink.

In one embodiment, the crystal matching layer operates as a reflective layer.

In one embodiment, the flow of current in the multilayer device is vertical.

### BRIEF DESCRIPTION OF THE DRAWINGS

FIG. 1 illustrates a cross sectional view of an exemplary multilayer transistor device in accordance with known techniques.

FIG. 2 illustrates a cross sectional view of an exemplary multilayer transistor device in accordance with known techniques.

FIG. 3 illustrates a cross sectional view of an exemplary multilayer structure in accordance with an exemplary embodiment.

FIG. 4 illustrates a cross sectional view of an exemplary multilayer structure in accordance with an exemplary embodiment.

FIG. 5 illustrates a cross sectional view of an exemplary multilayer structure in accordance with an exemplary embodiment.

FIG. 6 illustrates a cross sectional view of an exemplary multilayer structure in accordance with an exemplary embodiment.

FIG. 7 illustrates a top down view of an exemplary multilayer structure in accordance with the exemplary embodiment as shown in FIG. 6.

FIG. 8 illustrates a cross sectional view of an exemplary multilayer structure in accordance with known techniques.

FIG. 9 illustrates a cross sectional view of an exemplary multilayer structure in accordance with an exemplary embodiment.

FIG. 10 illustrates a cross sectional view of an exemplary multilayer structure in accordance with an exemplary embodiment.

### DETAILED DESCRIPTION

The various embodiments are described more fully with reference to the accompanying drawings. These example embodiments are provided so that this disclosure will be thorough and complete, and will fully convey the scope of the invention to readers of this specification having knowledge in the technical field. Like numbers refer to like elements throughout. The drawings presented herein may not be drawn to scale.

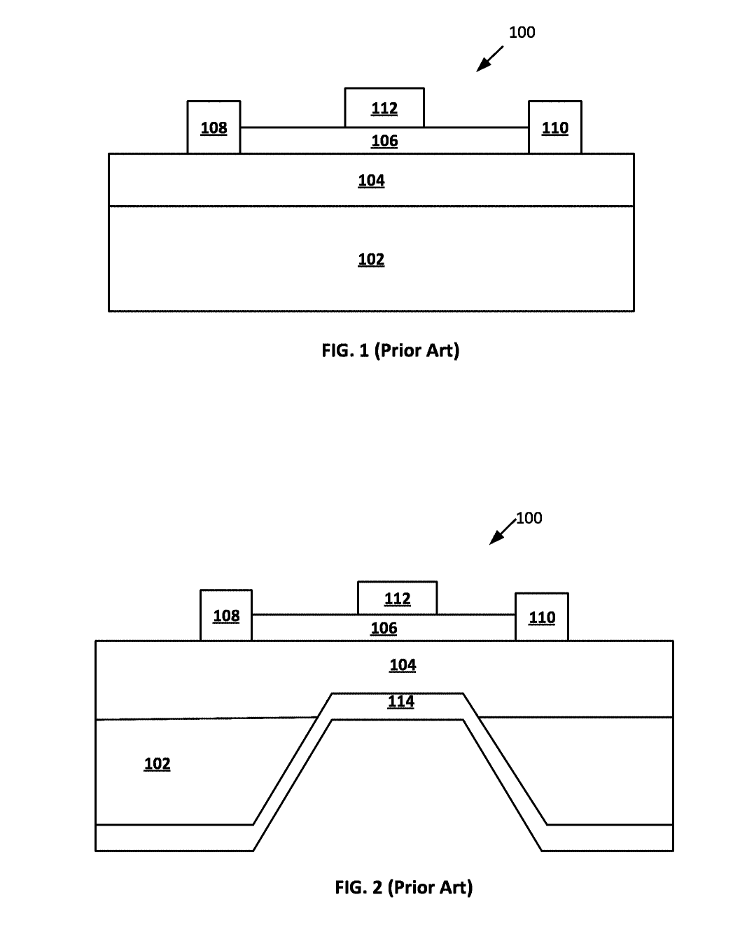

To appreciate the instant invention it is helpful to reference the current state of semiconductor devices. FIG. 1 illustrates multilayer structure 100, which is a known configuration of a high electron mobility transistor (HEMT). Multilayer structure includes substrate 102, GaN layer 104, AlGaN thin film 106, source 108, drain 110, and gate 112. Substrate 102 may be comprised of silicon, SiC, or sapphire.

Similarly FIG. 2 illustrates a different embodiment of multilayer structure 100. In this embodiment of multilayer structure 100, second backside gate 114 is implemented by etching the backside of multilayer structure 100 and metallizing the backside of multilayer structure 100 to form a backside gate.

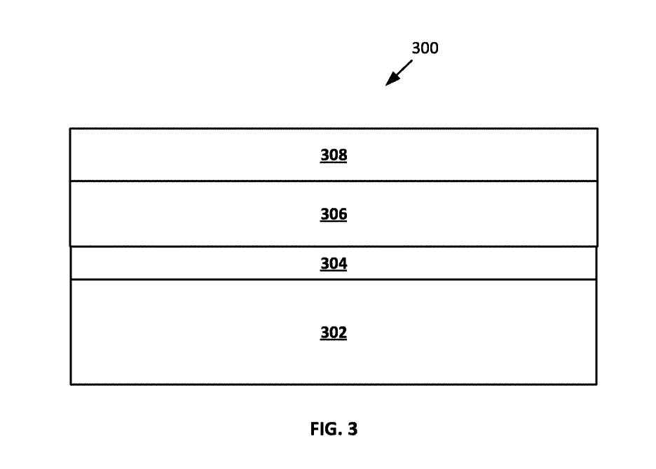

Unlike multilayer structure 100, multilayer structure 300 makes use of a crystal matching layer (CML) which allows multilayer structure 300 to have numerous benefits over the preexisting multilayer structure 100. FIG. 3 illustrates a first embodiment of multilayer structure 300. Multilayer structure 300 comprises of substrate 302, CML 304, semiconductor layer 306, and device layer 308. Substrate 302 may be may be comprised of graphite, graphene, sapphire, molybendum, CuMo, SiC, silicon, rare earth oxides (REO), LiAlO2, ceramics such as poly-AlN, and like materials. CML 304 may be deposited on substrate 302 by any suitable deposition method including but not limited to physical vapor deposition (PVD), chemical vapor deposition (CVD), atomic layer deposition (ALD), molecular beam epitaxy (MBE), and the like. CML 304 may be comprised of a metal and/or metal alloys. Semiconductor layer 306 may be deposited on CML 304 by any suitable deposition method including but not limited to PVD, CVD, ALD, and MBE. In one embodiment, semiconductor layer 306 comprises a member of the solid solution gallium nitride (GaN), and/or its alloys with aluminum (Al), indium (In), boron (B), including and not limited to: aluminum nitride (AlN), aluminum gallium nitride (AlGaN), gallium nitride (GaN), indium nitride (InN), indium gallium nitride (InGaN), and boron nitride (BN). Device layer 308 may be comprised of any suitable device structure. For example, an LED, RF filter, or HEMT structure. Many other devices may benefit from multilayer structure 300, including but not limited to photocathodes, photomultiplier tubes, klystrons, free-electron lasers, laser diode cavities, and laser diodes.

In one embodiment, the lattice constant of CML 304 is substantially matched to the lattice constant of the semiconductor layer 306. The CML may comprise two or more constituent elements, for example of two constituents, a first chemical element and a second chemical element, to form an alloy. The constituent elements may have similar crystal structures at room temperature, such as an HCP structure. In addition to crystal structures, the constituent elements may have similar chemical properties. In one embodiment, the first and second chemical elements may both belong to group four elements (e.g. titanium (Ti), zirconium (Zr), hafnium (Hf) and rutherfordium (Rf)), alloys of the group four elements, nitrides of the group four elements, and the alloys further alloyed with the elements of tantalum (Ta), boron (B), silicon (Si). The alloy may comprise a third chemical element or more elements which have similar crystal structures and similar chemical properties. The different chemical elements and the proportions of those chemical elements that make up the alloy(s) of CML 304 may be modified to substantially match semiconductor layer 306, according to the lattice constant of the semiconductor layer 306.

In order for the lattice constant of the CML to substantially match the lattice constant of the semiconductor layer the lattice constant of the CML must be within the range of +/−1-3% of the lattice constant of the semiconductor layer. For example, the CML may be comprised of ZrTi and the semiconductor layer may be comprised of GaN. In another example, the CML layer be comprised of HfTi and the semiconductor layer be comprised of AlGaN. For example, 12 atomic percent of In in InGaN semiconductor for Green LEDs would have a lattice constant of 3.23 Angstroms and could be substantially matched with 99 atomic percent of Zr alloyed with 1 atomic percent of Ti. In another example, GaN semiconductor which is commonly used in LEDs and Transistors may have a 3.19 Angstrom lattice constant, and substantially matched with 86 atomic percent of Zr alloyed with 14 atomic percent of Ti. In another example, AN with a 3.11 Angstrom lattice constant may be substantially matched by 57 atomic percent of Zr alloyed with 43 atomic percent of Ti. In all of these specific examples, Zr may be replaced by Hf and alloyed with Ti in similar ratios of atomic percent. In all stated cases the lattice constant of the metal alloy is matched within 3% of the semiconductor's lattice constant.

In one embodiment the coefficient of thermal expansion (CTE) of CML 304 is substantially matched to the CTE of the semiconductor layer 306. In order for the CTE of CML 304 to substantially match the CTE of the semiconductor layer 306, the CTE of the CML must be within the range of +/−15%. For example, the CML may be comprised of 86 atomic percent pure Zr and 14 atomic percent of Ti and the semiconductor layer may be comprised of GaN. In this example, the CTE of Zr, upon cooling to room temperature is 5.7 ppm/mK (ppm per meter Kelvin) and CTE of Ti is 8.5 ppm/mK. To determine if weighted average of the metal alloy to matches lattice within 15% we calculate: 0.86 times 5.7 plus 0.14 times 8.5, which yields 6.09 ppm/mK for the ZrTi alloy or within 10.7% of the CTE value of GaN (5.5 ppm/mK). In another example the CML may be comprised of 86% pure Hf and 14% Ti and the semiconductor may be comprised of GaN. For this example, the calculations are as follows: the weighted average of 0.86 times 5.9 (for Hf) plus 0.14 times 8.5, yields 6.26 ppm/mK which is within 13.8% of the value of GaN. In the specific case of semiconductor layer 306 being comprised of GaN, the 15% matching of the CTE enables semiconductor layer 306 to be grown as thick as 8 microns (1×10⁻⁶ meters) on 200 m diameter substrate 302 with less than 50 microns of maximum bow or warp for multilayer structure 300. In addition, substantially matching the CTE when semiconductor layer 306 is comprised of GaN enables growing semiconductor layer 306 to be grown as thick as 5 microns with less than 25 microns of bow or warp in multilayer structure 300. As the diameter of substrate 302 increases from 200 mm to 300 mm, the maximum thickness of semiconductor layer 306 reduces to 5 microns and 2.5 microns to meet a maximum bow specification of 50 microns and 25 microns respectively, with the properties of the substrate and the semiconductor layer staying the same.

CML 304 may be both substantially lattice and CTE matched to semiconductor layer 306. This is advantageous when the total thickness of multilayer structure 300 is less than 8 microns for a 200 mm substrate or 5 microns for a 300 mm substrate. In situations where the total thickness of the multilayer structure is greater than 8 microns it may be advantageous to have the substrate be CTE matched to semiconductor layer 306 instead of the CTE of CML 304 being substantially matched to the CTE of semiconductor layer 306. Having a close CTE match becomes more important as the diameter of the multilayer structure grows, and as the thickness of the sum of the semiconductor layer and the active device layer increase beyond 8 microns. In the latter case, the substrate may match the average CTE of semiconductor layer and the device layer.

When the substrate of the multilayer structure is used to CTE match the semiconductor layer what is considered substantially matched may depend on the application of multilayer structure. In one embodiment, the substrate's CTE must be within ±5% of the semiconductor layer's CTE to be substantially matching. For example, in order for a substrate to be substantially matched with GaN (having an approximate CTE of 5.6), the substrate must have a CTE between 5.32 and 5.88. The CTE of molybdenum is approximately 5.4, and according to the preferred embodiment, is substantially matched to the CTE of GaN. Applications in power semiconductor discretes and GaN based IC's, or high current density optoelectronic devices; of which creating significant thermal stresses during fabrication of semiconductor device layer on the substrate would benefit from a substantial match in CTE in accordance with the preferred embodiment. On the other hand, a silicon substrate with an approximate CTE of 2.6, would not be substantially matched to the CTE of the GaN film according to the preferred embodiment. According to the preferred embodiment, other materials that substantially match GaN include but are not limited to: Zirconium, Molybdenum, pure Arsenic, ZrTi (86:14 atomic percent), Carbide, and multigrained or polycrystalline Aluminum Nitride ceramic (1 to 1 atomic ratio).

In one embodiment, a substrate's CTE substantially matches the semiconductor layer's CTE if the substrate's CTE is within 1 (unit of ppm per degree Kelvin) of the semiconductor layer's CTE. In accordance with this embodiment, other materials that substantially match GaN include, but are not limited to: Zirconium, Osmium, Hafnium, Chromium, Molybdenum, Cerium, Rhenium, Tantalum, Iridium, Ruthenium, Tungsten, Praseodymium, Germanium, InAs, InP, InSb, AlAs, AlP, GaP, GaAs, pure Arsenic, Molybdenum-Copper, alloys of ZrTi, alloys of HfTi, Carbide, and poly-Aluminum Nitride ceramic (1 to 1 atomic ratio), Titanium, alloys of Molybdenum, alloys of Tungsten, alloys of Nickel, alloys of Niobium, alloys of Iridium, Kovar, alloys of Neodymium, Molybdenum-Copper, metal alloys of Ti, alloys of Zr, alloys of Hf, Carbide, poly-Aluminum Nitride ceramic of varying atomic proportions, alumina ceramic, titania, polycrystalline SiC. Typical applications requiring a substantially matched CTE according to this embodiment include, but are not limited to, thermal annealing, thermal degas or cleaning steps, physical or chemical film growth, recrystallization steps, metal contact firing steps, implantation and subsequent annealing, or any circuit fabrication steps (mask growth, etch/pattern, metallization, chemical-mechanical planarization (CMP), etc) that requires temperature heat up/cool down steps in the range of 1400 Celsius to room temperature and must remain below 50 microns of substrate or wafer bow, over any wafer diameter.

In another embodiment, a substrate's CTE substantially matches the semiconductor layer's CTE if the substrate's CTE is within 0.5 (unit of ppm per degree Kelvin) of the III-N film's CTE. For example, molybdenum has a CTE of approximately 5.4, which is within 0.5 of the CTE (unit of ppm per degree Kelvin) of GaN. In accordance with this embodiment, other materials that substantially match GaN include, but are not limited tomolybdenum, pure Arsenic, Chromium, ZrTi (86:14), Carbide, Germanium, Osmium, Zirconium, Hafnium, InSb, Kovar, and poly-Aluminum Nitride ceramic (1 to 1 atomic ratio). Typical applications requiring a substantially matched CTE according to this embodiment include, but are not limited to, thermal annealing, thermal degas or cleaning steps, physical or chemical film growth, recrystallization steps, metal contact firing steps, implantation and subsequent annealing, or any circuit fabrication step (mask growth, etch/pattern, metallization, CMP, etc) that requires temperature heat up/cool down steps in the range of 1400 Celsius to room temperature, and must remain below 25 microns of substrate or wafer bow, over any wafer diameter.

In one embedment, CML 304 is used as a buried extremely high thermal conductivity layer to take away heat from multilayer structure 300 during operation and processing. A benefit of having the CML act as a thermal conductivity layer is that is one of the first layers deposited, thus it can provide thermal protection for the substrate during the fabrication of multilayer substrate. In one embodiment, the CML is comprised of ZrTi or HfTi. These alloys conduct heat and diffuse the heat laterally to keep the multilayer structure in an acceptable temperature range during device operation (e.g. below 350 degrees Celsius). In some embodiments, the CML may have additions comprised of Al or Cu to improve the thermal conductivity of the CML after establishing a substantial lattice match between the CML and the semiconductor layer. The thickness range of the CML may also be modified based on the amount of thermal conductivity needed, but should ideally remain in the range of 100 nm to 1 um.

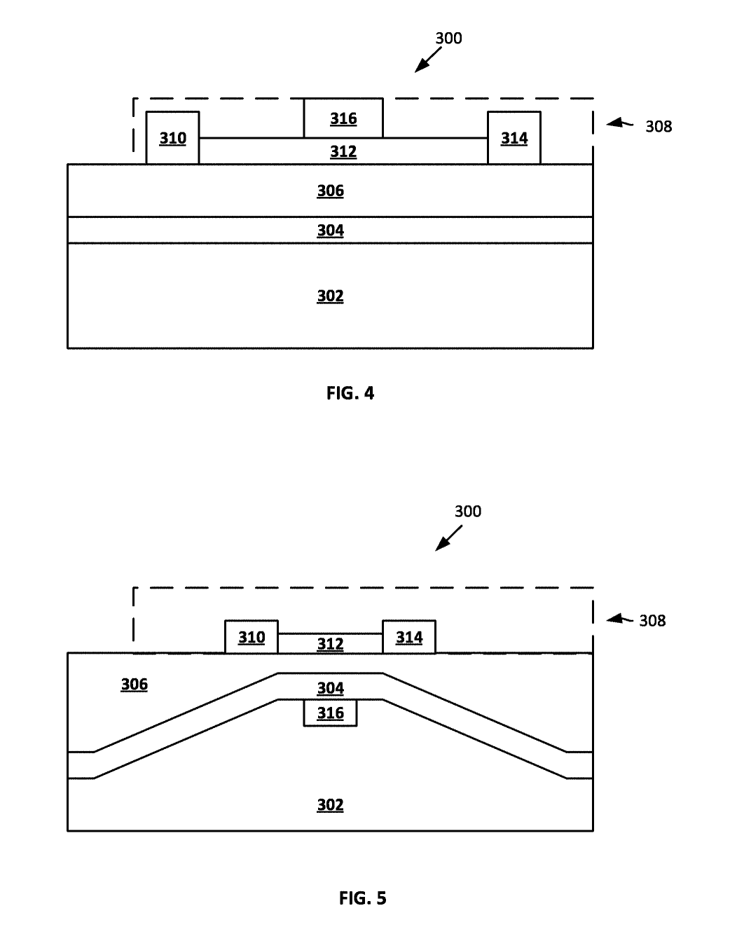

FIG. 4 illustrates an exemplarily embodiment of multilayer structure 300 as a double gate HEMT. The device layer 308 of multilayer structure 300 comprises a thin film of AlGaN 312, source 310, drain 314, and gate 316. The semiconductor layer 306 is a thin film of GaN. CML 304 functions as a second buried gate for the multilayer device. The CML is able to be utilized as a second buried gate because it serves as a back side ohmic contact for multilayer structure 300. In comparison to the prior art, the CML allows a factor of 100 to 1000 reduction in defect densities such as threading dislocations in semiconductor layer 306, and the CML enables a significantly thinner semiconductor layer 306 to be grown (5 to 10 times thinner than the prior art). The latter has immediate cost reductions in devices, 5-10 times reduction in growth time, and enables the CML to be within 1 micron of the AlGaN layer 312 to semiconductor layer 306 interface where the 2 dimensional electron gas (2DEG) resides, or the high electron mobility channel of the transistor in multilayer structure 300. This enables an efficient field effect to penetrate from an energized CML layer to modulate the 2DEG conduction from source to drain, or in other words, to pinch off the conduction channel at greater than 100 GigaHertz rate for efficient radio frequency transistor action

The double gate structure as shown in FIG. 4 is analogous to prior art FIG. 2 in the sense that it is a HEMT with two gates. However, the structure illustrated in FIG. 4 has the aforementioned advantages over the traditional double gate HEMT. In addition, there is no need for backside etching of the substrate to create a second gate. Second, the thin film of GaN's thickness can be less than or equal to 1 micron, while maintain extremely low defect densities. In the current state of the art of GaN HEMTs, (as shown in FIG. 2), the GaN layer 104 ranges from 5 to 10 microns and has 100 to 1000 larger defect densities. This negatively impacts device performance in several ways including but not limited to: higher cost to grow devices (8-10 hour growth time), limiting the standoff voltage of transistors to <600 volts, and switching speeds to <10 GigaHertz. In stark contrast, the present invention can be produced in 1-2 hours growth time, standoff voltage are capable of >3000 Volts, and switching speeds are capable of >100 GigaHertz.

In one embodiment multilayer structure 300 is comprised of layer a silicon 111 wafer that is 750 microns to 1.0 mm thick having a 200 mm or 300 mm diameter (302), ZrTi (86%:14% alloy) 500 nanometers to 1.0 micron thick (304), n-type GaN 1.0 to 5.0 micron thick (306), AlGaN (25% Al, 75% Ga) having 0.1 micron to 0.5 micron thickness (312). Please note variations may exist in layer 304 and layer 306 to achieve desired defect density in layer 306. Similarly, AlGaN layer 312 may grow in thickness by factor of 1 to 5 times to minimize leakage currents to the gate 316. Insulation layers may be deposited on the device layers 308 and between gate 316 and AlGaN layer 312 to minimize surface leakage paths. Insulation layers may be comprised of nitrides and oxides, and include, but are not limited to silicon nitride and silicon dioxide. Similarly, variations may exist in metal contact metal formulas for 310, 314 and 316 contacts, including Ag/Al, and Ti/Au admixtures, along with variations in the relative thickness. Typically, first elements are in the range of 5-50 nm thick and the second element 1 to 5 micron thick. In addition, multiple layers may be stacked as desired to improve the contact resistance.

FIG. 5 illustrates an exemplary embodiment of multilayer structure 300 as a single gate HEMT. In this embodiment, the device layer 308 of multilayer structure 300 comprises a thin film of AlGaN 312, source 310, drain 314 and gate 316. In one embodiment, AlGaN 312 has a thickness of 0.1 micron to 0.5 micron. The semiconductor layer is a film of GaN, which may either be thick or thin. CML 304 functions as the single gate in this embodiment. In order to improve the CML's field effect control voltage Ag/Al may be deposited on the CML and then the CML may be annealed, this process is known as firing the contact, where the CML is acting as a back side Schottky contact. The benefit of annealing the CML in this manner is that the source 310 and the drain 314 can be positioned closer together which helps create a higher density multilayer structure. The benefits of the configuration illustrated in FIG. 5 are a decrease in both device process cost and complexity as well as a higher packing density of devices per wafer. In other embodiments, Au may be fired into the CML as an alternate to Ag/Al or in addition to Ag/Al in order to further increase the CML's current conduction.

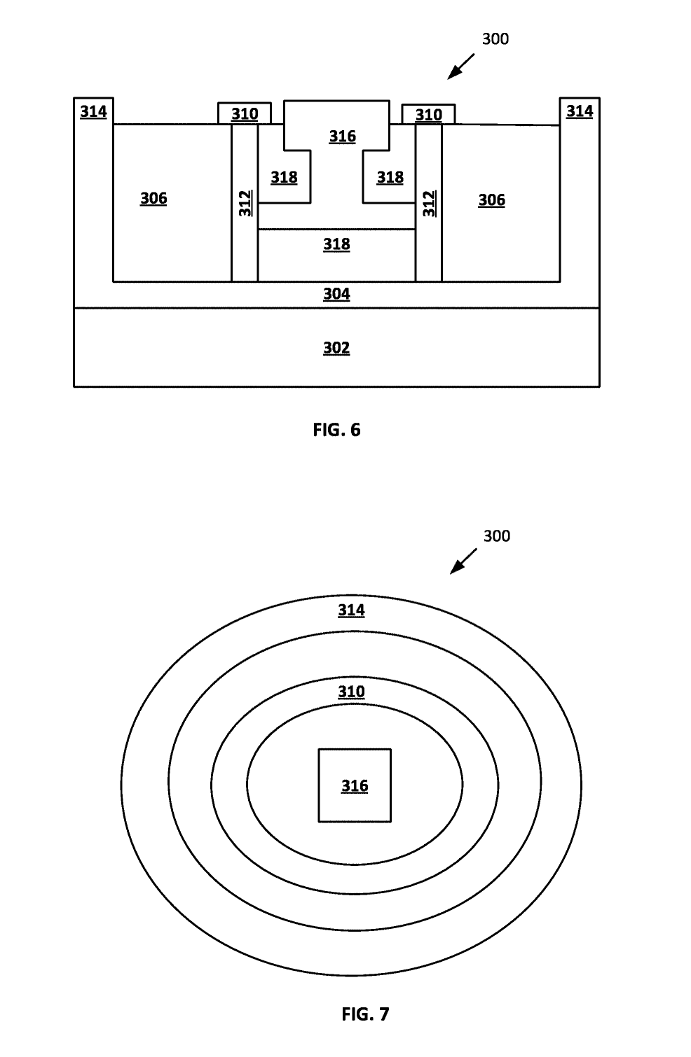

FIG. 6 illustrates an exemplary embodiment of multilayer structure 300 as a vertical structure. In this embodiment, the multilayer structure 300 comprises of insulating layer 318 (e.g. oxide layer of SiO₂). CML 304 also functions as the ohmic contact for transistor drain 314. Furthermore, thin film AlGaN 312 is now arranged in a vertical manner. The ohmic contact property of CML allows for the multilayer structure 300 be implemented as a vertical transistor. The current will now flow vertical (i.e. from the source to the drain) instead of in the traditional horizontal fashion (as would happen in FIGS. 1 and 2.) The vertical current flow removes lateral current crowding effects presented in known planar structures resulting from source and drains in close proximity in the plane, and enables greater than 10,000 voltage standoff by having a large separation between energized source and drain contacts not allowed in planar horizontal devices, and allows for extremely high current (greater than 5 Amps/mm²) to flow between the source and the large back side drain contact forming a large disc. In one embodiment multilayer structure 300 is comprised of Silicon 111 wafer that is 750 microns to 1.0 mm thick having a 200 mm or 300 mm diameter (302), ZrTi (86%:14% alloy) 500 nanometers to 1.0 micron thick (304), n-type GaN 1.0 to 5.0 micron thick (306), AlGaN (25% Al, 75% Ga) having 0.1 micron to 0.5 micron thickness (312). silicon dioxide at 0.1 to 0.5 the thickness of layer 306 (318). Please note variations may exist in layer 304 and 306 to achieve desired defect density in layer 306. Similarly, the AlGaN may grow in thickness by factor of 1 to 5 times to minimize leakage currents to the gate. In some embodiments, insulating layers may deposited on the surface of multilayer structure 300 and between gate 316 and AlGaN layer 312 to minimize surface leakage paths. These insulating layers may be comprised of nitrides and oxides and may include, not limited to, silicon nitride and silicon dioxide. Similarly, variations may exist in metal contact metal formulas for 310 and 316 contacts, including Ag/Al, and Ti/Au admixtures, along with variations in the relative thickness. Typically, first elements are in the range of 5-50 nm thick and the second element 1 to 5 micron thick. In addition, multiple layers in 310 and 316 may be stacked as desired to improve the contact resistance. Although FIG. 6 illustrates CML 304 being an ohmic contact for the transistor drain it is also within the scope of this invention to have CML 304 function as the ohmic contact for the transistor source as well.

FIG. 7 illustrates a top down view of the embodiment of multilayer structure 300 as illustrated in FIG. 6. This view shows one approach with cylindrical symmetry, which includes but is not limited to enabling a very large packing density for HEMT circuits in accordance with FIG. 6.

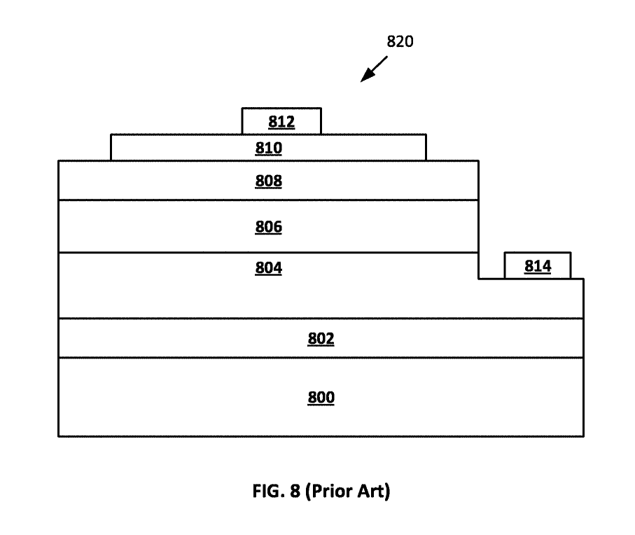

FIG. 8 illustrates an exemplary embodiment of multilayer LED structure 820. In this embodiment LED structure 820 comprises silicon or sapphire substrate 800, 1 um-3 um AlGaN buffer layer 802, 3 um-5 um N type GaN layer 804, 15 nm-80 nm multiple quantum well layer 806, 0.1 um-0.5 um P type GaN layer 808, 200 nm-300 nm transparent conductive oxide (TCO) contact of indium tin oxide 810, anode 812 and cathode 814.

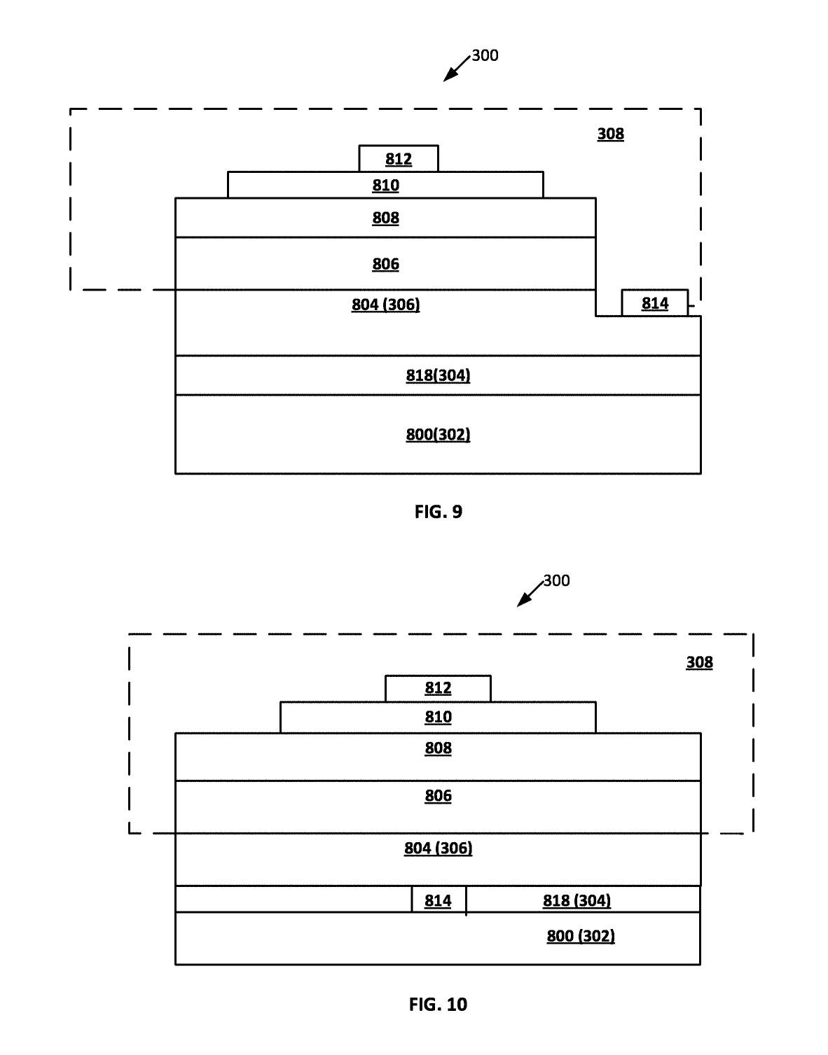

FIG. 9 illustrates an exemplary embodiment of multilayer structure 300 as an LED device, which improves upon the previously known multilayer LED structure 820. For sake of clarity multilayer structure 300 has been renumbered according to FIG. 8 to show the distinctions and advantages of the invention. However, corresponding references to FIG. 3 are shown in parentheses. Multilayer structure 300 has some of the same components as LED structure 820. However, multilayer structure 300 has CML 818. In one embodiment, CML 818 is comprised of HfTi or ZrTi. CML 818 allows for the removal of AlGaN buffer layer 802 from multilayer device 300. In addition the implementation of CML 818 allows N type GaN layer 804 to be reduced in size to less than or equal to 1 um from 3 um-5 um in LED structure 820. The reduction of layer 804 and the removal of layer 802 allows multilayer structure 300 to be 4 um to 8 um shorter than LED structure 820. In addition, these changes also allow fabrication time to be reduced from 8 hours (for LED structure 820) to 2 hours (for multilayer structure 300).

FIG. 10 illustrates an alternate exemplary embodiment of multilayer structure 300 as an LED device Similar to the embodiment illustrated in FIG. 5, due to its current conduction qualities, CML 818 is used as a backside cathode. In one embodiment, Au is fired into the CML in order to improve the current condition qualities of the CML with the N type GaN layer 804. The backside cathode contact allows for the vertical flow of current from the anode down to the cathode. This vertical flow of current allows multilayer structure 300 to handle extremely high current. For example, state of the art high brightness LEDs produce light with 25 Amps per square cm to 50 Amps per square cm, current density at >80% normalized efficiency, latter decreasing with drooping efficiency as more current is moved through device. The present vertical LED would increase the forward current density to >500 Amps per square cm with >95% normalized efficiency over the full forward current density range. Similar to the embodiment illustrated in FIG. 9, this embodiment also removes the AlGaN buffer layer and reduces the size of the N type GaN layer, thus reducing fabrication time from 8 hours to 2 hours.

The CML may be used as a reflective mirror layer, which is especially useful for LEDs. In one embodiment, the CML is comprised of ZrTi or HFTi. The CML reflects ultra violet light and visible light. As known in the art, visible light has approximately frequencies between 4-7.5×1014 Hz, wavelengths between 750 nm-400 nm and quantum energies of 1.65-3.1 eV. Ultraviolet has frequencies approximately between 7.5×1014-3×1016 Hz, wavelengths between 405 nm-10 nm, and quantum energies between 3.1-124 eV. In order to operate as an effective reflective layer the thickness of the CML layer is chosen to be approximately equal (i.e. within 5 nm) to ¼ of the wavelength of interest. For example uv-blue has an approximate wavelength of 405 nm, thus, in one embodiment, approximately ¼ of 405 is 100 nm, so the CML would have a thickness of 100 nm. Chart 1 below shows experimental results of the reflectance of a CML comprised of ZrTi and/or HfTi.

The color of light is shown along the horizontal axis, and the corresponding reflectance is shown on the vertical, as % R. Typically for a typical eye response, 450 is used as the lower limit of visible blue light, and 450 nm and below is considered uv light in the curve. Samples T001 T002 are samples with HfTi, and all other samples T003 to T005 have ZrTi as a single layer optimized to reflect 300 nm light.

In one embodiment, the multilayer structure creates a Bragg mirror by alternating layers of the CML and a thin nitride layer (i.e. AlN or other insulator). In such an embodiment, the thin nitride layers (i.e. AlN or other insulator) are deposited via PVD sputter or another suitable deposition method. Using the above example of uv-blue light, the sequence of 100 nm CML layer alternated with 25 nm to 100 nm of AlN is repeated at least 3 steps. The Bragg mirror with this configuration results in at least 95% reflectance. This high reflectance is achieved due in part to the atomic number for Hf and Zr. When using Bragg geometry there is only a need for 3 repeats (wherein one layer of CML and thin nitride layer is 1 repeat) to be performed using Hf and/or Zr.

Many modifications and other example embodiments set forth herein will bring to mind to the reader knowledgeable in the technical field to which these example pertain to having the benefit of the teachings presented in the foregoing descriptions and the associated drawings. Therefore, it is to be understood that the embodiments are not to be limited to the specific ones disclosed and that modifications and other embodiments are intended to be included within the scope of the claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims.

What is claimed is:

1. A multilayer device comprising:
a substrate;
a first layer deposited on the substrate, wherein the first layer comprises one or more metal alloys;
a second layer deposited on the first layer, wherein the second layer comprises a III-Nitride semiconductor, wherein a lattice constant of the first layer is substantially matched to a lattice constant of the second layer; and
a third layer formed on the second layer, wherein the first layer is an ohmic contact for the third layer.

2. The multilayer device of claim 1, wherein the third layer comprises an LED structure configured to produce visible or ultraviolet light.

3. The multilayer device of claim 1, wherein the third layer comprises a transistor structure configured to operate at high power or at high speed.

4. The multilayer device of claim 1, wherein the third layer comprises a radio frequency filter.

5. The multilayer device of claim 1, wherein a coefficient of thermal expansion of the first layer is substantially matched to a coefficient of thermal expansion of the second layer.

6. The multilayer device of claim 1, wherein the first layer is configured to operate as a conductive heat sink.

7. The multilayer device of claim 1, wherein the multilayer device is less than 8 microns thick.

8. The multilayer device of claim 1, wherein the first layer is configured to reflect 95% or more of ultra violet light and visible light.

9. The multilayer device of claim 1, wherein a coefficient of thermal expansion of the substrate is substantially matched to a coefficient of thermal expansion of the second layer.

10. The multilayer device of claim 1, wherein flow of current in the multilayer structure is vertical.

11. A method for manufacturing a multilayer structure comprising:
depositing, a first layer on a substrate, wherein the first layer comprises one or more metal alloys;
depositing, a second layer on the first layer, wherein the second layer comprises a III-Nitride semiconductor, wherein a lattice constant of the first layer is substantially matched to a lattice constant of the second layer; and
depositing, a third layer formed on the second layer, wherein the first layer is an ohmic contact for the third layer.

12. The method of claim 9, wherein the third layer comprises an LED structure configured to produce visible or ultraviolet light.

13. The method of claim 9, wherein the third layer comprises a transistor structure configured to operate at high power or at high speed.

14. The method of claim 9, wherein the third layer comprises a radio frequency filter.

15. The method of claim 9, wherein a coefficient of thermal expansion of the first layer is substantially matched to a coefficient of thermal expansion of the second layer.

16. The method of claim 9, wherein the first layer is configured to operate as a conductive heat sink.

17. The method of claim 9, wherein the multilayer device is less than 8 microns thick.

18. The method of claim 9, wherein the first layer is configured to reflect 95% or more of ultra violet light and visible light.

19. The method of claim 9, wherein flow of current in the multilayer structure is vertical.
